(19) United States
(12) Patent Application Publication
(10) Pub. No.: US 2018/0269131 A1
(43) Pub. Date: Sep. 20, 2018

(54) COMPONENT COOLING SYSTEM

(71) Applicant: Facebook, Inc., Menlo Park, CA (US)

(72) Inventor: Jacob Na, Los Gatos, CA (US)

(21) Appl. No.: 15/464,258

(22) Filed: Mar. 20, 2017

(51) Int. Cl. H01L 23/473; H01L 23/40

(52) U.S. Cl. CPC H01L 23/473; H01L 23/40

(57) ABSTRACT

Technology is provided for a component cooling system. The system can include a cooling block assembly and a radiator. The cooling block assembly includes a mounting bracket and a coolant block positioned in the mounting bracket. The coolant block includes a cold plate volume in fluid communication with an inlet plenum and an outlet plenum. A pump is positioned between the inlet plenum and the outlet plenum, coupled to the mounting bracket, and in fluid communication with the outlet plenum. The radiator includes a center tank having an inlet chamber in fluid communication with an outlet of the pump and an outlet chamber in fluid communication with the inlet plenum. A pair of end tanks are positioned on opposite sides of the center tank with core tubes extending between the inlet and outlet chambers and the pair of end tanks.

### TECHNICAL FIELD

This patent application is directed to computer component cooling systems and, more specifically, to liquid cooling systems.

### BACKGROUND

Cooling a component (e.g., microprocessor) can enhance the lifetime and/or performance of the component. Liquids allow the transfer of more heat from computer components being cooled than air, making liquid cooling systems desirable for high performance computer applications and for extending the life of components. Conventional liquid cooling systems typically comprise a sealed system incorporating a small radiator, a fan, a coolant block, and an optional pump. The coolant block is typically clamped on top of the component to be cooled. The coolant block transfers heat from the component to coolant circulating through the block. The coolant circulates passively or via a pump to a radiator where heat is rejected to the surrounding atmosphere.

### BRIEF DESCRIPTION OF THE DRAWINGS

Embodiments of the component cooling systems described herein may be better understood by referring to the following Detailed Description in conjunction with the accompanying drawings, in which like reference numerals indicate identical or functionally similar elements:

FIG. 1 is an isometric view of a component cooling system according to a representative embodiment.

FIG. 2 is an isometric view of the component cooling system shown in FIG. 1 as viewed from below.

FIG. 3 is a partial isometric view of the component cooling system with various components removed to illustrate the construction of the radiator.

The headings provided herein are for convenience only and do not necessarily affect the scope or meaning of the claimed embodiments. Further, the drawings have not necessarily been drawn to scale. For example, the dimensions of some of the elements in the figures may be expanded or reduced to help improve the understanding of the embodiments. Moreover, while the disclosed technology is amenable to various modifications and alternative forms, specific embodiments have been shown by way of example in the drawings and are described in detail below. The intention, however, is not to unnecessarily limit the embodiments described. On the contrary, the embodiments are intended to cover all suitable modifications, equivalents, and alternatives falling within the scope of the embodiments as defined by the appended claims.

### DETAILED DESCRIPTION

### Overview

Technology is provided for a component (e.g., microprocessor) cooling system. The disclosed cooling system includes a radiator having centrally located inlet and outlet connections which provide enhanced cooling performance and more compact and serviceable component packaging. In some embodiments, the system can include a cooling block assembly and a radiator. The cooling block assembly can include a mounting bracket and a coolant block positioned in the mounting bracket. The coolant block includes a cold plate volume in fluid communication with an inlet plenum and an outlet plenum. The cold plate is configured to be placed in close contact with a component thereby transferring heat from the component. A pump is positioned between the inlet plenum and the outlet plenum and is in fluid communication with the outlet plenum. The radiator includes a center tank having an inlet chamber in fluid communication with an outlet of the pump and an outlet chamber in fluid communication with the inlet plenum. A pair of end tanks are positioned on opposite sides of the center tank with core tubes extending between the inlet and outlet chambers and the pair of end tanks. The pump circulates coolant between the cooling block and the radiator to cool the component.

### GENERAL DESCRIPTION

Various examples of the devices introduced above will now be described in further detail. The following description provides specific details for a thorough understanding and enabling description of these examples. One skilled in the relevant art will understand, however, that the techniques discussed herein may be practiced without many of these details. Likewise, one skilled in the relevant art will also understand that the technology can include many other features not described in detail herein. Additionally, some well-known structures or functions may not be shown or described in detail below so as to avoid unnecessarily obscuring the relevant description.

The terminology used below is to be interpreted in its broadest reasonable manner, even though it is being used in conjunction with a detailed description of some specific examples of the embodiments. Indeed, some terms may even be emphasized below; however, any terminology intended to be interpreted in any restricted manner will be overtly and specifically defined as such in this section.

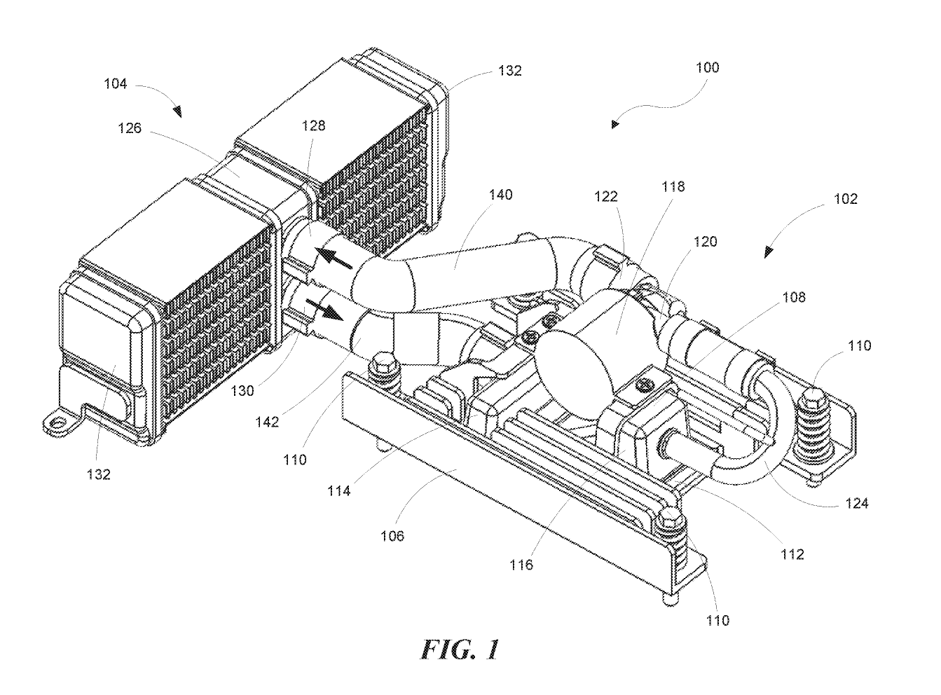

FIG. 1 illustrates a component cooling system 100 according to a representative embodiment. The component cooling system 100 can be used to cool any suitable component, such as the microprocessor of a central processing unit. The component cooling system 100 can include a cooling block assembly 102 and a radiator 104 interconnected with tubing assemblies 140 and 142. The cooling block assembly 102 includes a mounting bracket 106 and a coolant block 108 positioned in the mounting bracket 106. In some embodiments, the mounting bracket 106 includes spring loaded fasteners 110 to facilitate clamping or pressing the coolant block 108 against a component to be cooled.

The coolant block 108 can include a cold plate volume 112 in fluid communication with an inlet plenum 114 and an outlet plenum 116. A coolant, such as water, flows through the coolant block 108 and passes over a heat transfer plate or other heat sink member that conveys heat from the component (e.g., microprocessor) to the coolant in the cold plate volume 112 before the coolant exits through the outlet plenum 116, thereby drawing heat away from the component. A pump 118 is positioned between the inlet plenum 114 and the outlet plenum 116. The pump 118 is mounted to the mounting bracket 106 with fasteners as shown. An inlet 120 of the pump 118 is connected for fluid communication with the outlet plenum 116 via a transfer tube assembly 124.

In some embodiments, the radiator 104 includes a center tank 126 and a pair of end tanks 132 positioned on opposite sides of the center tank 126. The flow of coolant is divided so a first portion flows through tubes in the left side (one side) of the radiator, and a second portion of the coolant flows through tubes in the right side (other side) of the radiator. In some embodiments, the center tank 126 is positioned approximately midway between the pair of end tanks 132. The center tank 126 has an inlet connector 128 connected to an outlet 122 of the pump 118, and an outlet connector 130 connected to the inlet plenum 114. Centrally locating the inlet and outlet connectors 128/130 provides enhanced cooling performance, as explained more fully below, and provides more compact and serviceable component packaging. Typical component cooling system radiators have connections located at either end of the radiator in one of the end tanks 132, for example. In a typical microprocessor cooling application, the tubing connecting the pump and radiator in these conventional systems interferes with components mounted adjacent the processor, such as memory cards. The centrally located inlet and outlet connections 128/130 of the present system facilitate routing the coolant tubing (e.g., tubing assemblies 140/142) directly to the coolant block 108 and associated microprocessor (not shown) without interfering with any components (e.g., memory cards) located next to the microprocessor.

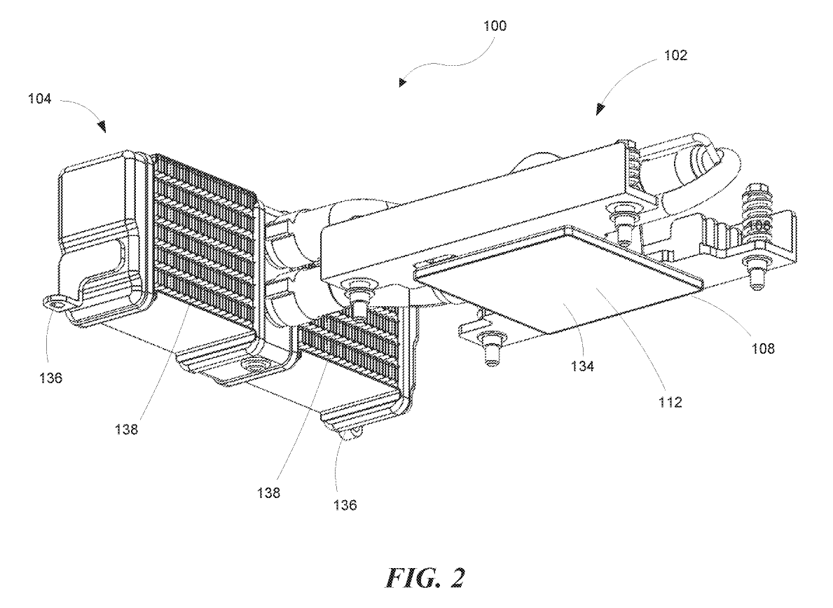

As shown in FIG. 2, the coolant block's cold plate volume 112 includes a planar heat transfer plate 134 configured to be placed in close contact with a component, thereby transferring heat from the component to coolant inside the coolant block 108. Also shown in FIG. 2, the radiator 104 can include mounting brackets 136 to attach the radiator 104 to a chassis or circuit board. In some embodiments, the radiator 104 includes a plurality of cooling fins 138 to transfer heat from coolant inside the radiator 104 to the surrounding air. In some embodiments, the cooling fins 138 can be corrugated metal (e.g., aluminum) soldered to core tubes within the radiator.

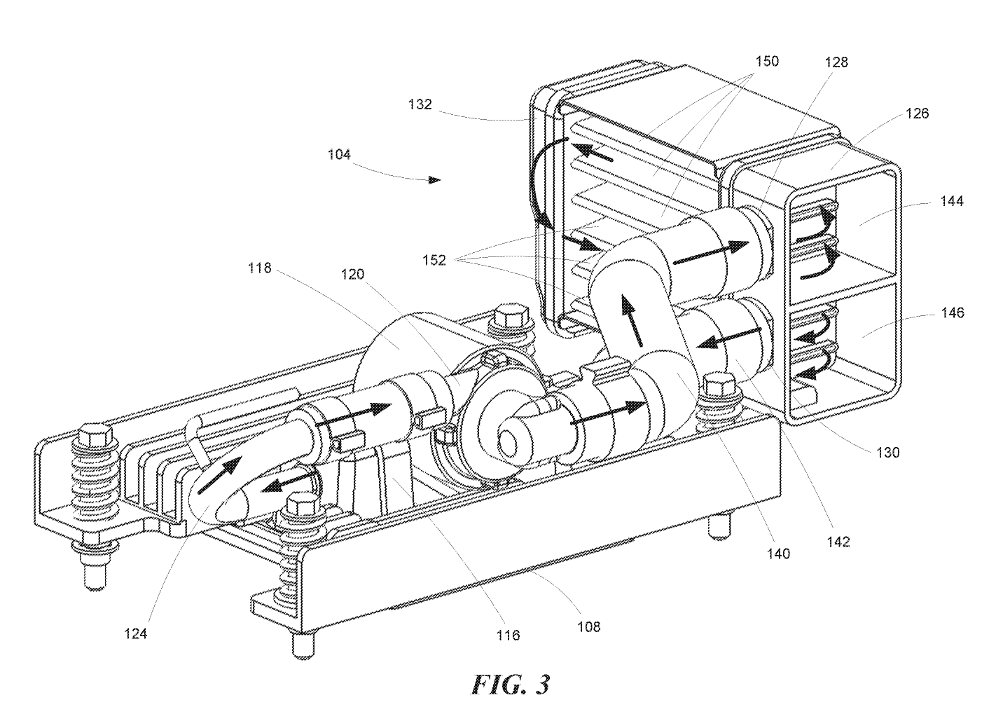

FIG. 3 illustrates a representative embodiment of the radiator 104 with the cooling fins 138 and a portion of the radiator removed to better illustrate the construction of the radiator and the flow of coolant through the radiator 104. The coolant flows through both sides of the radiator on opposite sides of the center tank 126, although only one side of the radiator is shown for purposes of illustration. The coolant is represented in the figures with arrows indicating the direction of flow. The center tank 126 can include an inlet (e.g., first) chamber 144 and an outlet (e.g., second) chamber 146. The inlet connector 128 extends from the inlet chamber 144 and the outlet connector 130 extends from the outlet chamber 146. In some embodiments, the inlet and outlet connectors 128/130 can comprise hose nipples soldered into the inlet and outlet chambers 144/146, respectively.

Three inlet core tubes 150 extend between the inlet chamber 144 and one of the pair of end tanks 132 and three outlet core tubes 152 extend between the end tank 132 and the outlet chamber 146. More or fewer core tubes can be used in various embodiments. It should also be appreciated that additional inlet and outlet core tubes 150 and 152 extend in the opposite direction to the other of the pair of end tanks 132.

In operation, the component to be cooled (not shown) heats the coolant in the coolant block 108 as it passes over the heat transfer plate 134 (FIG. 2) or other heatsink member, and the coolant flows from the outlet plenum 116 into the pump inlet 120 via the transfer tube assembly 124. The pump 118 pumps the heated coolant to the inlet chamber 144 via the tubing assembly 140. The coolant then flows away from the inlet chamber 144 through the inlet core tubes 150 in the radiator 104 coupled to the cooling fins 138 and into the end tank 132. The coolant next flows from the end tank 132 through the outlet core tubes 152 also in the radiator 104 coupled to the cooling fins 138, and toward the outlet chamber 146. Accordingly, the coolant flowing into the outlet chamber 146 is cooled via the flow through the radiator 104. The cooled coolant then returns to the coolant block 108 via the tubing assembly 142 and the inlet plenum 114 (FIG. 1). Centrally locating the inlet and outlet connectors 128/130 divides the coolant to flow through both sides of the radiator, which provides enhanced cooling performance by slowing down the flow through the radiator as compared to conventional radiators, thereby allowing more time for the coolant to be cooled. Centrally locating the inlet and outlet connectors 128/130 has the effect of causing the coolant to flow through additional turns, as compared to conventional radiators, which slows the coolant flow, thereby allowing more heat to dissipate via the core tubes 150/152 and the cooling fins 138 (FIG. 2).

### Remarks

The above description and drawings are illustrative and are not to be construed as limiting. Numerous specific details are described to provide a thorough understanding of the disclosure. However, in some instances, well-known details are not described in order to avoid obscuring the description. Further, various modifications may be made without deviating from the scope of the embodiments. Accordingly, the embodiments are not limited except as by the appended claims.

Reference in this specification to “one embodiment” or “an embodiment” means that a particular feature, structure, or characteristic described in connection with the embodiment is included in at least one embodiment of the disclosure. The appearances of the phrase “in one embodiment” in various places in the specification are not necessarily all referring to the same embodiment, nor are separate or alternative embodiments mutually exclusive of other embodiments. Moreover, various features are described which may be exhibited by some embodiments and not by others. Similarly, various requirements are described which may be requirements for some embodiments but not for other embodiments.

The terms used in this specification generally have their ordinary meanings in the art, within the context of the disclosure, and in the specific context where each term is used. It will be appreciated that the same thing can be said in more than one way. Consequently, alternative language and synonyms may be used for any one or more of the terms discussed herein, and any special significance is not to be placed upon whether or not a term is elaborated or discussed herein. Synonyms for some terms are provided. A recital of one or more synonyms does not exclude the use of other synonyms. The use of examples anywhere in this specification, including examples of any term discussed herein, is illustrative only and is not intended to further limit the scope and meaning of the disclosure or of any exemplified term. Likewise, the disclosure is not limited to various embodiments given in this specification. Unless otherwise defined, all technical and scientific terms used herein have the same meaning as commonly understood by one of ordinary skill in the art to which this disclosure pertains. In the case of conflict, the present document, including definitions, will control.

What is claimed is:

1. A component cooling system, comprising:
a radiator having a pair of opposed end tanks and a pair of centrally located fluid connectors positioned approximately midway between the end tanks; and
a cooling block assembly, including:
a mounting bracket;
a coolant block positioned in the mounting bracket and in fluid communication with one of the pair of centrally located fluid connectors; and
a pump coupled to the mounting bracket and in fluid communication with the other of the pair of centrally located fluid connectors.

2. The component cooling system of claim 1, wherein the radiator includes a center tank having a first chamber in fluid communication with the pump and a second chamber in fluid communication with the coolant block.

3. The component cooling system of claim 2, wherein the coolant block includes a cold plate volume in fluid communication with an inlet plenum and an outlet plenum.

4. The component cooling system of claim 3, wherein the first chamber is in fluid communication with an outlet of the pump and the second chamber is in fluid communication with the inlet plenum.

5. The component cooling system of claim 3, wherein the pump is positioned between the inlet plenum and the outlet plenum.

6. The component cooling system of claim 2, further comprising a first plurality of core tubes extending between the first chamber and the pair of opposed end tanks and a second plurality of core tubes extending between the second chamber and the pair of opposed end tanks.

7. The component cooling system of claim 6, wherein the radiator includes a plurality of cooling fins in contact with the first and second pluralities of core tubes.

8. A component cooling system, comprising:
a cooling block assembly, including:
a mounting bracket;
a coolant block positioned in the mounting bracket; and
a pump coupled to the mounting bracket in fluid communication with the coolant block; and
a radiator, including:
a center tank having a first chamber in fluid communication with the pump and a second chamber in fluid communication with the coolant block;
a pair of end tanks positioned on opposite sides of the center tank;
a first plurality of core tubes extending between the first chamber and the pair of end tanks; and
a second plurality of core tubes extending between the second chamber and the pair of end tanks.

9. The component cooling system of claim 8, wherein the coolant block includes a cold plate volume in fluid communication with an inlet plenum and an outlet plenum.

10. The component cooling system of claim 9, wherein the first chamber is in fluid communication with an outlet of the pump and the second chamber is in fluid communication with the inlet plenum.

11. The component cooling system of claim 9, wherein the pump is positioned between the inlet plenum and the outlet plenum.

12. The component cooling system of claim 9, wherein the radiator includes a plurality of cooling fins in contact with the first and second pluralities of core tubes.

13. The component cooling system of claim 9, wherein the center tank includes an inlet connector extending from the first chamber and an outlet connector extending from the second chamber.

14. The component cooling system of claim 9, wherein the center tank is positioned approximately midway between the pair of end tanks.

15. A component cooling system, comprising:
a cooling block assembly, including:
a mounting bracket;
a coolant block positioned in the mounting bracket including a cold plate volume in fluid communication with an inlet plenum and an outlet plenum; and
a pump positioned between the inlet plenum and the outlet plenum, coupled to the mounting bracket, and in fluid communication with the outlet plenum; and
a radiator, including:
a center tank having an inlet chamber in fluid communication with an outlet of the pump and an outlet chamber in fluid communication with the inlet plenum;
a pair of end tanks positioned on opposite sides of the center tank;
a first plurality of core tubes extending between the inlet chamber and the pair of end tanks;
a second plurality of core tubes extending between the outlet chamber and the pair of end tanks; and
a plurality of cooling fins in contact with the first and second pluralities of core tubes.

16. The component cooling system of claim 15, wherein the center tank is positioned approximately midway between the pair of end tanks.

17. The component cooling system of claim 16, wherein the center tank includes an inlet connector extending from the inlet chamber and an outlet connector extending from the outlet chamber.
